(19) United States
(12) Patent Application Publication
(10) Pub. No.: US 2021/0402430 A1
(43) Pub. Date: Dec. 30, 2021

(54) SYSTEMS AND METHODS FOR GRAFTING A MOLECULAR CODE ONTO A MATERIAL BY AN ATMOSPHERIC PLASMA TREATMENT

(71) Applicant: Illinois Tool Works Inc., Glenview, IL (US)

(72) Inventor: Rory Wolf, Hartford, WI (US)

(21) Appl. No.: 17/346,347

(22) Filed: Jun. 14, 2021

Related U.S. Application Data
(60) Provisional application No. 63/044,861, filed on Jun. 26, 2020.

(51) Int. Cl. B05D 1/00; H05H 1/24; C23C 14/32

(52) U.S. Cl. CPC B05D 1/62; C23C 14/32; H05H 1/47

(57) ABSTRACT

The present disclosure describes material surface treatment systems and methods for grafting a coded substance (e.g., a molecular code) to a material through a surface treatment process. In some examples, the material is subjected to a plasma discharge containing the molecular code, which is grafted onto the material at the molecular level thereby having little or no impact on the properties of the treated material.

### CROSS-REFERENCE TO RELATED APPLICATIONS

This application hereby claims priority to and the benefit of U.S. Provisional Application Ser. No. 63/044,861 entitled “Systems And Methods For Grafting A Molecular Code Onto A Material By An Atmospheric Plasma Treatment,” filed Jun. 26, 2020. The above listed U.S. application is hereby incorporated by reference in its entirety for all purposes.

### BACKGROUND

Some material surface treatment systems utilize high voltage electrodes to treat the surface of articles such as foils or films by electric discharge. Conventional treatment systems are used to modify a property of a material being treated. However, if information is to be added to the material, conventional systems are limited to conventional printing methods, which are easily altered, replicated, or removed. Accordingly, manufacturers would benefit from systems or methods for material surface treatment that embed information on the material in a more indelible manner.

### SUMMARY

Disclosed are systems and methods for material surface treatments for grafting a coded substance to a material through a surface treatment process. In particular, systems and methods employ an electrode to create a plasma containing the coded substance, which is then grafted onto the material during a plasma surface treatment process.

These and other features and advantages of the present invention will be apparent from the following detailed description, in conjunction with the appended claims.

### BRIEF DESCRIPTION OF THE DRAWINGS

The benefits and advantages of the present invention will become more readily apparent to those of ordinary skill in the relevant art after reviewing the following detailed description and accompanying drawings, wherein:

FIG. 1 is an example schematic diagram of a material surface treatment system, in accordance with aspects of this disclosure.

FIG. 2 is another example schematic diagram of a material surface treatment system, in accordance with aspects of this disclosure.

FIG. 3 is yet another example schematic diagram of a material surface treatment system, in accordance with aspects of this disclosure.

FIG. 4 provides a flowchart representative of example machine-readable instructions which may be executed by the example material surface treatment system of FIGS. 1-3 to graft a molecular code onto a material, in accordance with aspects of this disclosure.

The figures are not necessarily to scale. Where appropriate, similar or identical reference numbers are used to refer to similar or identical components.

### DETAILED DESCRIPTION

The present disclosure describes material surface treatment systems and methods for grafting a coded substance (e.g., a molecular code) to a material through a surface treatment process. In some examples, the material is subjected to a plasma discharge containing the molecular code, which is grafted onto the material at the molecular level thereby having little or no impact on the properties of the treated material.

In some examples, the material surface treatment systems and methods for grafting a coded substance includes a vaporizer to receive a solution comprising the molecular code. The vaporizer creates a vapor having the molecular code, which is then exposed to an electrode, where an electric discharge creates a plasma from ionized process gases and the vapor. The plasma is then applied to the material near the electrode, such that the plasma grafts the molecular code onto the material.

Material surface treatment systems may be equipped to treat a variety of materials (e.g., plastics, such as polyethylene and polypropylene) having surfaces with low surface tensions that inhibits bonding with surface treatments, such as printing inks, coatings, and/or adhesives. Material surface treatment systems are employed to alter the characteristics of a particular material (e.g., plastic and/or flexible substrates) for particular applications (e.g., inks, coatings, adhesives and/or laminations). For example, a plastic film generally needs some type of surface treatment to achieve suitable chemical bonding with an ink, adhesive, etc. This is contrasted with a porous material like paper, where ink is able to penetrate into the medium.

A variety of materials can be effectively treated using such systems and methods (e.g., polyethylene, polypropylene, nylon, vinyl, PVC, PET, metalized surfaces, foils, paper, and paperboard stocks).

Various techniques have been implemented to provide a desired material characteristic for such materials. For example, a corona treatment is a surface treatment that employs a relatively low temperature electrical corona discharge to change a surface characteristic of the material. Corona treatment, which employs one or more electrodes, provides desirable adhesion characteristics at a reasonable cost. A corona electrode generates a high voltage discharge and is effective to modify a surface energy of a working material (e.g., plastics, paper, foils, etc.).

Another example is a plasma treatment, where gases are injected into the electrode discharge to treat the material surface. For example, some materials are more receptive to plasma treatments rather than a corona treatment in order to achieve a desired material property, such as bonding characteristics.

By comparison to corona treatments, plasma treatments are often associated with higher cost and complexity, such as use of more complex electrodes and more process controls. Thus, greater implementation of plasma treatments has been limited in the industry. However, some materials respond more favorably to plasma treatments rather than corona treatments (e.g., fluoropolymers, polypropylenes, etc.).

As disclosed herein, both corona and plasma treatment systems, which employ corona electrodes and plasma electrodes, respectively, may be employed to graft a coded substance (e.g., a molecular code) to a material through a surface treatment process, as provided in the following examples.

Advantageously, the disclosed material surface treatment systems and methods are configured to graft the molecular code onto a material without impacting the desired properties of the material post treatment. Additionally, the material surface treatment systems and methods integrate the molecular code into the material at a molecular level, making removal of the coded information extremely difficult to introduce, alter, or remove, providing robust protections for the manufacturer of the material.

In disclosed examples, a material surface treatment system includes a vaporizer to receive a solution comprising a molecular code, the vaporizer to create a vapor having the molecular code, and an electrode to generate an electric discharge to create a plasma comprised of ionized process gases and the vapor and apply the plasma to a material near the electrode, wherein application of the plasma grafts the molecular code to the material.

In some examples, a grounding roll configured to engage with the material, the material to be subjected to the plasma discharged from the electrode as the plasma is drawn to the grounding roll, wherein the grounding roll is electrically connected to a reference voltage.

In examples, one or more properties of the material are altered as a result of the plasma application. In examples, the material is one of a polymer, synthetic wovens and/or nonwovens, natural fiber wovens, filaments, yarns, elastomers, or metals.

In some examples, the ionized process gases form a hydroxyl group, a carboxyl group, a carbonyl group, or an amine. In some examples, non-ionized process gases are introduced to the vaporizer, the vaporizer comprising a heater to heat the non-ionized process gases and the molecular solution to combine or vaporize the non-ionized process gases and the molecular solution.

In some examples, the electrode comprises one of a plasma electrode or a corona electrode. In some examples, the electrode is connected to an electrical power source configured to provide current to activate the electrode.

In some examples, the material is a rolled web. In examples, the material is a planar structure. In examples, the material is a multi-sided object.

In some disclosed examples, a material surface treatment system is configured for treatment of a planar object. The system includes a vaporizer to receive a solution comprising a molecular code, the vaporizer to create a vapor having the molecular code, an electrode to generate an electric discharge to create a plasma comprised of ionized process gases and the vapor, and one or more rollers to convey the planar object toward the electrode to apply the plasma to a material of the planar object near the electrode, wherein application of the plasma grafts the molecular code to the material.

In some examples, a grounding block opposite the electrode relative to the material, the material to be subjected to the plasma discharged from the electrode as the plasma is drawn to the grounding block, wherein the grounding block is electrically connected to a reference voltage. In examples, one or more properties of the material are altered as a result of the plasma application.

In some disclosed examples, a material surface treatment system configured for treatment of an object with a non-uniform geometry. The system includes a vaporizer to receive a solution comprising a molecular code, the vaporizer to create a vapor having the molecular code, an electrode to generate an electric discharge to create a plasma comprised of ionized process gases and the vapor, and a nozzle to apply the plasma to a material of the object near the electrode, wherein application of the plasma grafts the molecular code to the material.

In some examples, the electrode extends into a body. In examples, a filter arranged within the body to serve as a partial barrier between a first volume configured to receive the vapor and a second volume that includes one or more dielectric elements. In examples, the second volume is configured to subject the vapor to an electric discharge between the electrode and the dielectric elements, thereby creating the plasma.

In some examples, a non-linear conveyor configured to apply the molecular code by movement of the nozzle about the material. In some examples, the electrode comprises one of a plasma electrode or a corona electrode

As used herein, the term “power supply” refers to any device capable of, when power is applied thereto, supplying power to the material treatment system, including but not limited to inverters, converters, resonant power supplies, quasi-resonant power supplies, and the like, as well as control circuitry and other ancillary circuitry associated therewith. The term can include energy storage devices, and/or circuitry and/or connections to draw power from a variety of external power sources.

As used herein, a “circuit,” or “circuitry,” includes any analog and/or digital components, power and/or control elements, such as a microprocessor, digital signal processor (DSP), software, and the like, discrete and/or integrated components, or portions and/or combinations thereof.

As used herein, “power conversion circuitry” and/or “power conversion circuits” refer to circuitry and/or electrical components that convert electrical power from one or more first forms (e.g., power output by a generator) to one or more second forms having any combination of voltage, current, frequency, and/or response characteristics. The power conversion circuitry may include safety circuitry, output selection circuitry, measurement and/or control circuitry, and/or any other circuits to provide appropriate features.

As used herein, the terms “first” and “second” may be used to enumerate different components or elements of the same type, and do not necessarily imply any particular order.

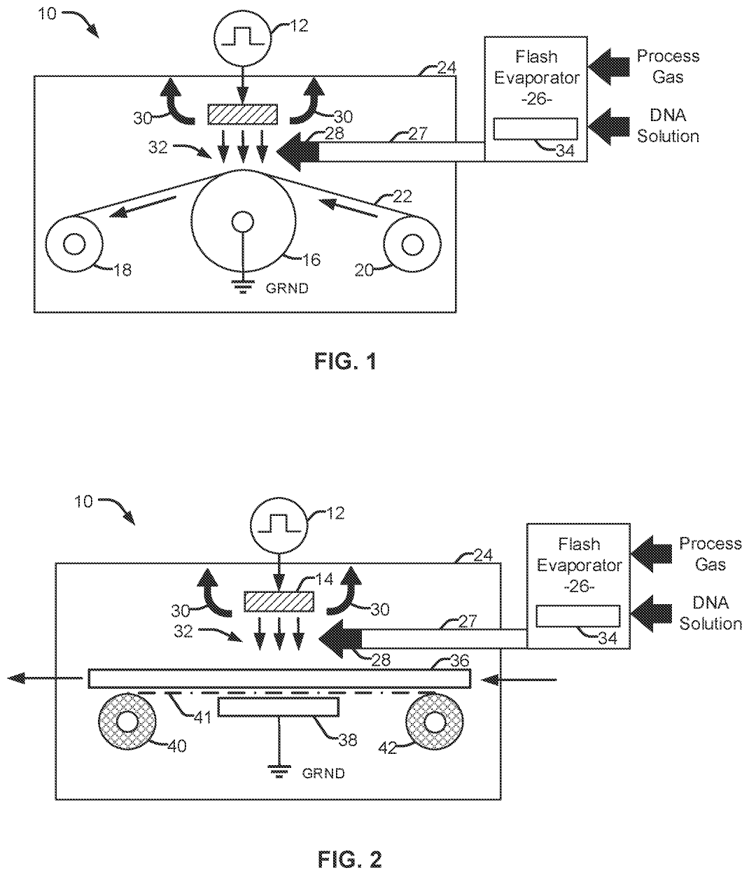

FIG. 1 illustrates a material treatment system 10 that includes a discharge electrode 14 in electrical communication with power source 12. The electrode 14 may be arranged in an enclosure 24, which may create a controlled environment (e.g., controlled pressure, temperature, containment of byproducts, etc.) in which to conduct a material treatment process. In some examples, a ground roller 16 is employed (e.g., a grounded bare roll with a pathway to ground or other reference voltage) and arranged to allow a web of material 22 (e.g., fabric, paper, plastic, film, etc.) to pass near the electrode 14 in order to be treated by plasma 32 generated by the electrode 14 discharge.

In some examples, the discharge electrode 14 consists of a dielectric tube (e.g., ceramic) or a stainless steel electrode, and the ground roller 16 consists of a stainless steel roller, or a ceramic- or glass-covered ground roller, both of which cooperate to distribute a high voltage charge uniformly along the length of the electrode 14.

The power source 12 providing power input may include a high voltage transformer, power converter, and/or a power supply (e.g., mains power). In some examples, power source 12 provides an applied power density to the discharge electrode 14 between approximately 10 watt-minutes per meter² and 110 watt-minutes per meter², and in some examples between approximately 20 watt-minutes per meter² and 60 watt-minutes per meter², however other ranges are also contemplated.

As shown, the system 10 includes a vaporizer or flash evaporator 26 to receive one or more inputs, such as a gas or fluid. In the example of FIG. 1, the inputs include a solution comprising a molecular code and/or a process gas. The molecular code may contain information regarding specific traits, which may be grafted onto the material 22 at a molecular level. The information may include a location, an entity, a process, for instance, which can later be revealed by analysis of the chemical make-up of the material.

In some examples, the molecular code solution will consist of between approximately 20 to 110 parts of deionized water to 1 part molecular code solution, and in some examples between approximately 40 to 80 parts deionized water to 1 part DNA solution, however other ranges are also contemplated. In some examples, the molecular code solution will be introduced into the vaporizer 26 at a rate between approximately 0.1 milliliter per centimeter of electrode length per minute and 1.0 milliliter per centimeter of electrode length per minute, and in some examples between approximately 0.3 milliliter per centimeter of electrode length per minute and 0.8 milliliter per centimeter of electrode length per minute, however other ranges are also contemplated.

In some examples the process gases can comprise a mixture of different gases, including a mix of nitrogen and oxygen. For instance, the process gas mixture can include nitrogen with a concentration between approximately 99% and 80% and, in some examples, between approximately 97% and 88%, however other ranges are also contemplated. The plasma gas mixture can include oxygen with a concentration between approximately 20% and 1%, and in some examples between approximately 12% and 3%, however other ranges are also contemplated. In some examples, the process gas or mixture gas may form, when ionized, certain functional groups, such as a hydroxyl group, a carboxyl group, a carbonyl group, or an amine, as a non-limiting list of examples.

The vaporizer 26 receives a vapor 28 having the molecular code and/or the process gas, which is then conveyed to an area between the electrode 14 and the ground roller 16 via conduit 27 (e.g., via a fan, pump, etc.). In examples, the vaporizer 26 includes a heater 34 to generate heat to transform the inputs into a vapor 28. For instance, the vaporizer 26 can heat the inputs at a temperature between approximately 100 degrees Celsius and 250 degrees Celsius, and in some examples between approximately 180 degrees Celsius and 220 degrees Celsius, however other ranges are also contemplated.

In some examples, one or more sensors (e.g., a flow meter, a pressure sensor, etc.), or valves may be employed to monitor and/or control the rate and/or amount of the molecular code solution and/or the process gas into the flash evaporator 26 and/or into the enclosure as vapor 28. Thus, once the molecular code solution has been vaporized, the vapor 28 can be conveyed by the process gas to the electrode 14 at a flow rate between approximately 1 liter per centimeter of electrode length per minute and 10 liter per centimeter of electrode length per minute, and in some examples between approximately 2 liter per centimeter of electrode length per minute and 5 liter per centimeter of electrode length per minute, however other ranges are also contemplated.

As the vapor 28 reaches the electrode 14, a high voltage electric discharge creates a plasma 32 which ionizes molecules of the process gases and the molecular code. For example, the functional group of ionized molecules in the process gas (e.g., a hydroxyl group) serve as a binding agent for the molecular code, which are then attracted to the ground roll 16, drawing the plasma 32 with the molecular code to the material 22. The plasma 32 also propagates collisions of ionized molecules. As a result, the molecular code is grafted onto the material 22. For instance, the molecular code is grafted at a molecular level, thereby having little or no impact on the properties of the treated material. In particular, during the material surface treatment process, one or more properties of the material may be altered, such as to adjust porosity, adhesive capacity, or strength of the material, as a non-limiting list of properties. Exemplary material treatment processes may produce one or more byproducts 30 (e.g., water vapor, unreacted gases, ozone), which may be drawn away from the treatment area as an exhaust and/or for additional processing.

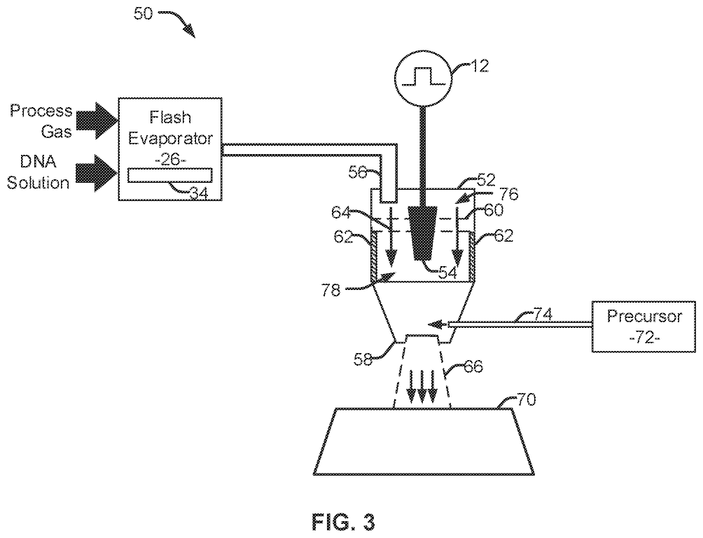

In disclosed examples, the material is one of a polymer, synthetic wovens and/or nonwovens, natural fiber wovens, filaments, yarns, elastomers, or metals, as a non-limiting list of properties. In each case, the material may have be presented for treatment in a variety of configurations. For example, the material may be presented as a substantially flexible web, film, foil, etc., such that conveyance of the material is transferred from a source roll 20 to a receiving roll 18. In some examples, the material is presented as substantially planar, such as a rigid, semi-rigid, or flexible sheet, plate, board, etc. (see, e.g., the example system of FIG. 2). In some examples, the material is presented with a non-uniform geometry, such that application of the molecular code may be implemented by use of a non-linear conveyor and/or a moveable electrode arrangement (see, e.g., the example system of FIG. 3). In each example configuration, the systems and methods are designed to apply the molecular code in accordance with disclosed techniques.

In some examples, the material treatment process is controlled by one or more programs executed by one or more control circuits, such as on an integrated or remote computing platform. For example, the control circuits, control circuitry, and/or controller may include digital and/or analog circuitry, discrete and/or integrated circuitry, microprocessors, digital signal processors (DSPs), Field Programmable Gate Arrays (FPGAs), and/or other logic circuitry, and/or associated software, hardware, and/or firmware. Control circuits or control circuitry may be located on one or more circuit boards that form part or all of a controller, and are used to control the material treatment process. The control circuit may include a memory, which may include volatile and/or non-volatile memory devices and/or other storage device, to store information, such as program instructions, for execution by the control circuit.

A material that has been treated by the processes disclosed herein can be tested to reveal the embedded coded information. For example, the material may be subjected to one or more chemical testing techniques (e.g., electrophoresis, chromatography, spectroscopy, mass spectrometry, etc.), thereby decompiling the information contained in the molecular code. The results of such testing indicate the presence or absence of the molecular code.

FIG. 2 illustrates another example material treatment system 10 that is configured for treatment of substantially planar items for treatment. As shown in FIG. 2, a conveyance system includes one or more of a platform and/or belt 41 upon which to rest a material structure 36 (e.g., a substantially planar structure, such as a rigid, semi-rigid, or flexible sheet, plate, board, etc.) as it traverses an area between the electrode 14 and a grounding block 38. In some examples, the platform 41 is driven by one or more rollers 40, 42, and operates as a conveyor for the material structure 36. In additional or alternative examples, the material structure 36 rests upon one or more rollers 40, 42 and is conveyed through the enclosure 24 without the aid of platform 41.

FIG. 3 provides yet another example material surface treatment system 50 that is configured for treatment of an object 70 with a non-uniform geometry. For example, object 70 may be a three-dimensional object with multiple surfaces, one or more of which is to be treated in order to graft the molecular code to a material of the object 70. Thus, application of the molecular code may be implemented by use of a non-linear conveyor, and/or by movement of the electrode about the item and/or movement of the item about the electrode.

In the example of FIG. 3, the power source 12 provides power to an electrode 54, which extends into a body 52. A filter 60 is arranged within the body 52 to serve as a partial barrier between a first volume 76 configured to receive a vapor 64 and a second volume 78 that includes one or more dielectric elements 62. The vapor 64 is conveyed from vaporizer 26 via conduit 56, the vapor 64 including the molecular code and/or the process gas. The vapor 64 introduced to the second volume 78 where it is subjected to an electric discharge between electrode 54 and dielectric elements 62, thereby creating a plasma 66 to be applied to object 70 via nozzle 58. In this manner, the molecular code is grafted onto the material of the object 70 at the area exposed to the plasma 66.

In some examples, a precursor gas, such as nitrogen, may be introduced into the body 52 via a conduit 74. Additionally or alternatively, the system 50 may be fully or partially enclosed in an enclosure. In some examples, the object 70 may be grounded, either via a direct path to ground, via a connector to a ground or reference voltage.

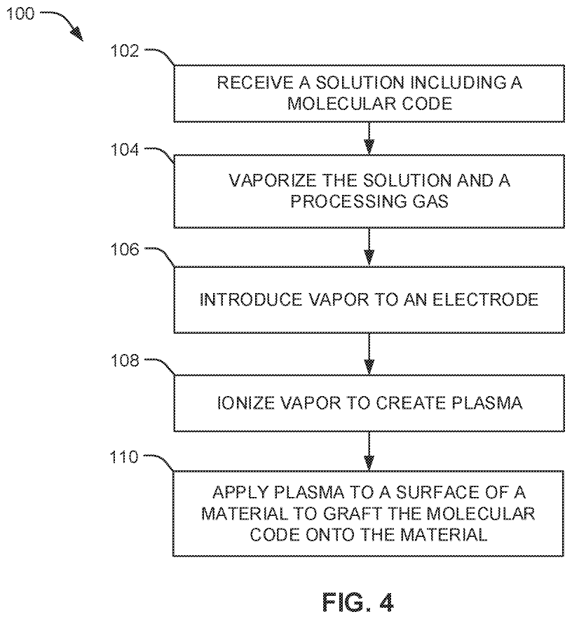

FIG. 4 provides a flowchart representative of example instructions 100 which may be executed by the example material surface treatment system of FIGS. 1-3 to graft a molecular code onto a material, in accordance with aspects of this disclosure. At block 102, a solution including a molecular code is received, such as at an evaporator or vaporizer. At block 104, the solution and a processing gas are vaporized and introduced to an electrode in block 106. At block 108, the vapor is ionized to create a plasma, which is applied to a surface of a material in order to graft the molecular code onto the material in block 110.

As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. For example, systems, blocks, and/or other components of disclosed examples may be combined, divided, re-arranged, and/or otherwise modified. Therefore, the present method and/or system are not limited to the particular implementations disclosed. Instead, the present method and/or system will include all implementations falling within the scope of the appended claims, both literally and under the doctrine of equivalents.

What is claimed is:

1. A material surface treatment system comprising:
a vaporizer to receive a solution comprising a molecular code, the vaporizer to create a vapor having the molecular code; and
an electrode to generate an electric discharge to create a plasma comprised of ionized process gases and the vapor and apply the plasma to a material near the electrode, wherein application of the plasma grafts the molecular code to the material.

2. The material surface treatment system of claim 1, further comprises a grounding roll configured to engage with the material, the material to be subjected to the plasma discharged from the electrode as the plasma is drawn to the grounding roll, wherein the grounding roll is electrically connected to a reference voltage.

3. The material surface treatment system of claim 1, wherein one or more properties of the material are altered as a result of the plasma application.

4. The material surface treatment system of claim 1, wherein the material is one of a polymer, synthetic wovens and/or nonwovens, natural fiber wovens, filaments, yarns, elastomers, or metals.

5. The material surface treatment system of claim 1, wherein the ionized process gases form a hydroxyl group, a carboxyl group, a carbonyl group, or an amine.

6. The material surface treatment system of claim 1, wherein non-ionized process gases are introduced to the vaporizer, the vaporizer comprising a heater to heat the non-ionized process gases and the molecular solution to combine or vaporize the non-ionized process gases and the molecular solution.

7. The material surface treatment system of claim 1, wherein the electrode comprises one of a plasma electrode or a corona electrode.

8. The material surface treatment system of claim 1, wherein the electrode is connected to an electrical power source configured to provide current to activate the electrode.

9. The material surface treatment system of claim 1, wherein the material is a rolled web.

10. The material surface treatment system of claim 1, wherein the material is a planar structure.

11. The material surface treatment system of claim 1, wherein the material is a multi-sided object.

12. A material surface treatment system configured for treatment of a planar object, the system comprising:
a vaporizer to receive a solution comprising a molecular code, the vaporizer to create a vapor having the molecular code;
an electrode to generate an electric discharge to create a plasma comprised of ionized process gases and the vapor; and
one or more rollers to convey the planar object toward the electrode to apply the plasma to a material of the planar object near the electrode, wherein application of the plasma grafts the molecular code to the material.

13. The material surface treatment system of claim 12, further comprises a grounding block opposite the electrode relative to the material, the material to be subjected to the plasma discharged from the electrode as the plasma is drawn to the grounding block, wherein the grounding block is electrically connected to a reference voltage.

14. The material surface treatment system of claim 12, wherein one or more properties of the material are altered as a result of the plasma application.

15. A material surface treatment system configured for treatment of an object with a non-uniform geometry, the system comprising:
a vaporizer to receive a solution comprising a molecular code, the vaporizer to create a vapor having the molecular code;
an electrode to generate an electric discharge to create a plasma comprised of ionized process gases and the vapor; and
a nozzle to apply the plasma to a material of the object near the electrode, wherein application of the plasma grafts the molecular code to the material.

16. The material surface treatment system of claim 15, wherein the electrode extends into a body.

17. The material surface treatment system of claim 16, further comprising a filter arranged within the body to serve as a partial barrier between a first volume configured to receive the vapor and a second volume that includes one or more dielectric elements.

18. The material surface treatment system of claim 17, wherein the second volume is configured to subject the vapor to an electric discharge between the electrode and the dielectric elements, thereby creating the plasma.

19. The material surface treatment system of claim 15, further comprising a non-linear conveyor configured to apply the molecular code by movement of the nozzle about the material.

20. The material surface treatment system of claim 15, wherein the electrode comprises one of a plasma electrode or a corona electrode.
